(19) United States
(12) Patent Application Publication
(10) Pub. No.: US 2025/0183156 A1
(43) Pub. Date: Jun. 5, 2025

(54) STACKED VIA STRUCTURE, SEMICONDUCTOR DEVICE INCLUDING STACKED VIA STRUCTURE AND METHOD OF MANUFACTURING SAME

(71) Applicant: DB HiTek Co., Ltd., Bucheon-si (KR)

(72) Inventors: In Gon BAE, Gunpo-si (KR); Seung Hoon LEE, Chungcheongbuk-do (KR)

(21) Appl. No.: 18/408,902

(22) Filed: Jan. 10, 2024

(30) Foreign Application Priority Data
Dec. 5, 2023 (KR) 10-2023-0174131

(51) Int. Cl. H01L 23/522; H01L 21/768; H10B 63/00

(52) U.S. Cl. CPC H01L 23/5226; H01L 21/76877; H10B 63/30

(57) ABSTRACT

Provided is a stacked via structure, a semiconductor device including the stacked via structure and a method of manufacturing the same. More particularly, proposed is a stacked via structure, a semiconductor device including the stacked via structure and a method of manufacturing the same, which ensure an alignment margin between upper and lower vias by forming a conductive sidewall at an upper end of the lower via or a lower end of the upper via to surround the upper or lower end.

### CROSS REFERENCE TO RELATED APPLICATION

The present application claims priority to Korean Patent Application No. 10-2023-0174131, filed Dec. 5, 2023, the entire contents of which is incorporated herein for all purposes by this reference.

### BACKGROUND OF THE INVENTION

### Field of the Invention

The present disclosure relates to a stacked via structure, a semiconductor device including the stacked via structure and a method of manufacturing the same. More particularly, the present disclosure relates to a stacked via structure, a semiconductor device including the stacked via structure and a method of manufacturing the same, which ensure an alignment margin between upper and lower vias by forming a conductive sidewall at an upper end of the lower via or a lower end of the upper via to surround the upper or lower end.

### Description of the Related Art

Through-substrate vias can be used to connect a semiconductor chip to another semiconductor chip or to a package substrate. For example, through-substrate vias are used in a variety of semiconductor devices such as image sensors, stacked memories, or interposers.

FIG. 1 is a reference cross-sectional view to illustrate misalignment occurring in a conventional via stack structure.

Referring to FIG. 1, in a stacked via structure formed between a lower metal line 910 and an upper metal line 970, a lower via 930 and an upper via 950 have sides that are directly connected to each other, and thus misalignment between the upper and lower vias 930 and 950 may occur. When such misalignment occurs, there may be instances where electrical signals cannot be properly applied to a device. If the width of the vias 930 and/or 950 is made large to prevent misalignment, that is, for alignment stability, pitches in a via formation process increase, which causes the problem of increasing the overall size of the device. To prevent misalignment while maintaining the width size of the via (930 and/or 950), additional masks or high-performance equipment need to be used to accurately perform a process, which may significantly increase manufacturing costs.

In order to solve the above-described problems, the inventors of the present disclosure propose a stacked via structure with an improved structure, a semiconductor device including the stacked via structure and a method of manufacturing the same, details of which will be described later.

### DOCUMENT OF RELATED ART

(Patent Document 1) U.S. Patent Application Publication No. 2022/0216404 A1 “MEMORY DEVICE HAVING VIA LANDING PROTECTION”

### SUMMARY OF THE INVENTION

Accordingly, the present disclosure has been made keeping in mind the above problems occurring in the related art, and the present disclosure is intended to provide a stacked via structure, a semiconductor device including the stacked via structure and a method of manufacturing the same, which ensure a sufficient alignment margin between upper and lower vias by forming a sidewall containing a conductive material at an upper end of the lower via or a lower end of the upper via to surround the upper or lower end in a stacked via structure.

In addition, an objective of the present disclosure is to provide a stacked via structure, a semiconductor device including the stacked via structure and a method of manufacturing the same, which prevent process efficiency from decreasing by forming a sidewall not only in a peripheral region but also in a cell region.

In addition, an objective of the present disclosure is to provide a stacked via structure, a semiconductor device including the stacked via structure and a method of manufacturing the same, which prevent additional processes for forming a sidewall as much as possible by allowing the sidewall to be formed by deposition and etching without using a separate mask pattern.

In addition, an objective of the present disclosure is to provide a stacked via structure, a semiconductor device including the stacked via structure and a method of manufacturing the same, which ensure a substantial alignment margin between upper and lower vias by having at least one side of the upper surface of a sidewall not covered by a second insulation film.

The present disclosure may be implemented by an embodiment having the following configuration in order to achieve the above-described objectives.

According to an embodiment of the present disclosure, there is provided a stacked via structure including: a first source metal and a first drain metal disposed apart from each other in an interlayer insulation film; a pair of lower vias, wherein one of the pair of lower vias is connected to the first source metal and the other of the pair of lower vias is connected to the first drain metal within the interlayer insulation film; a pair of upper vias, wherein one of the pair of upper vias is connected to an upper part of the one of the pair of lower vias and the other of the pair of upper vias is connected to an upper part of the other of the pair of lower vias within the interlayer insulation film; a second source metal connected to the one of the pair of upper vias and a second drain metal connected to the other of the pair of upper vias, wherein the second source metal and the second drain metal are disposed apart from each other, and a sidewall disposed at an end of each of the pair of lower vias or at an end of each of the pair of upper vias to surround the end.

According to another embodiment of the present disclosure, in the stacked via structure according to the present disclosure, the sidewall may have a conductive metal material.

According to still another embodiment of the present disclosure, in the stacked via structure according to the present disclosure, the sidewall may surround an upper outer surface of each of the pair of lower vias.

According to still another embodiment of the present disclosure, in the stacked via structure according to the present disclosure, the sidewall may be formed by an etching process without a separate mask pattern.

According to still another embodiment of the present disclosure, in the stacked via structure according to the present disclosure, the sidewall may have a flat bottom surface and a curved upper surface.

According to an embodiment of the present disclosure, there is provided a semiconductor device including a stacked via structure. The semiconductor device includes: a substrate; a plurality of gate regions disposed on the substrate, one of the plurality of gate regions being disposed in a cell region and another of the plurality of gate regions being disposed in a peripheral region; a source region and a drain region disposed in the cell region and another source region and another drain region disposed in the peripheral region, wherein the source region and the drain region are disposed apart from each other and the another source region and the another drain region are disposed apart from each other within the substrate; a plurality of contact plugs, a first contact plug being connected to the source region, a second contact plug being connected to the drain region, a third contact plug being connected to the another source region, and a fourth contact plug being connected to the another drain region; a first source metal connected to the first contact plug, a first drain metal connected to the second contact plug, another first source metal connected to the third contact plug, and another first drain metal connected to the fourth contact plug, wherein the first source metal and the first drain metal are disposed apart from each other and the another first source metal and the another first drain metal are disposed apart from each other, a pair of first lower vias, wherein one of the pair of first lower vias is connected to the another first source metal and the other of the pair of first lower vias is connected to the first drain metal in the peripheral region; a pair of first upper vias, wherein one of the pair of first upper vias is connected to an upper end of the one of the pair of first lower vias and the other of the pair of first upper vias is connected to an upper end of the other of the pair of first lower vias in the peripheral region; and a sidewall disposed on an end of each of the pair of first lower vias.

According to another embodiment of the present disclosure, the semiconductor device including a stacked via structure according to the present disclosure may further include: a second lower via connected to the first drain metal in the cell region; a memory cell connected to an upper part of the second lower via in the cell region; and a second upper via connected to an upper side of the memory cell in the cell region.

According to still another embodiment of the present disclosure, in the semiconductor device including a stacked via structure according to the present disclosure, the memory cell may include: a lower electrode connected to the upper part of the second lower via; a switching layer disposed on the lower electrode; an upper electrode disposed on the switching layer, and an insulation film layer disposed on the upper electrode.

According to still another embodiment of the present disclosure, in the semiconductor device including a stacked via structure according to the present disclosure, the sidewall may be disposed at an upper end of each of the pair of first lower vias or at an upper end of the second lower via, the sidewall surrounding the upper end of each of the pair of first lower vias or the upper end of the second lower via.

According to still another embodiment of the present disclosure, in the semiconductor device including a stacked via structure according to the present disclosure, the sidewall may have a conductive metal material.

According to still another embodiment of the present disclosure, in the semiconductor device including a stacked via structure according to the present disclosure, the lower electrode may have a bottom surface that has a width larger than a width of a top surface of the second lower via.

According to still another embodiment of the present disclosure, in the semiconductor device including a stacked via structure according to the present disclosure, the upper electrode may have a top surface that has a width larger than a width of a bottom surface of the second upper via.

According to still another embodiment of the present disclosure, in the semiconductor device including a stacked via structure according to the present disclosure, the sidewall may have an upper surface configured to contact a bottom surface of each of the pair of first upper vias.

According to an embodiment of the present disclosure, there is provided a method of manufacturing a semiconductor device including a stacked via structure. The method includes: forming a first insulation film on a substrate; forming a contact plug within the first insulation film; forming a lower metal connected to the contact plug on the first insulation film; forming a second insulation film on the first insulation film to cover the lower metal; forming a lower via in the second insulation film; etching an upper surface of the second insulation film to expose an upper side of the lower via; forming a conductive film on the second insulation film; and forming a sidewall surrounding the upper side of the lower via by etching the conductive film.

According to another embodiment of the present disclosure, in the method of manufacturing a semiconductor device including a stacked via structure according to the present disclosure, the sidewall may be formed by an etching process without a separate mask pattern.

According to still another embodiment of the present disclosure, the method of manufacturing a semiconductor device including a stacked via structure according to the present disclosure may further include: completing the second insulation film by forming an insulation film up to an upper end of the lower via on the second insulation film that is etched.

According to still another embodiment of the present disclosure, the method of manufacturing a semiconductor device including a stacked via structure according to the present disclosure may further include: forming an additional insulation film on the second insulation film; and forming an upper via connected to the lower via in the additional insulation film to form a stacked via structure.

According to still another embodiment of the present disclosure, the method of manufacturing a semiconductor device including a stacked via structure according to the present disclosure may further include: forming an upper metal connected to the upper via on the upper via.

According to still another embodiment of the present disclosure, in the method of manufacturing a semiconductor device including a stacked via structure according to the present disclosure, at least one area of an upper surface of the sidewall is not covered by the second insulation film.

The present disclosure has the following effects by the above configurations.

According to the present disclosure, a sufficient alignment margin can be ensured between upper and lower vias by forming a sidewall containing a conductive material at an upper end of the lower via or a lower end of the upper via to surround the upper or lower end in a stacked via structure.

In addition, deterioration in process efficiency can be prevented by forming a sidewall not only in a peripheral region but also in a cell region.

In addition, additional processes for forming a sidewall can be prevented as much as possible by allowing the sidewall to be formed by deposition and etching without using a separate mask pattern

In addition, a substantial alignment margin between upper and lower vias can be ensured by having at least one side of the upper surface of a sidewall not covered by a second insulation film.

Meanwhile, it should be added that even if effects are not explicitly mentioned herein, the effects described in the following specification expected by the technical features of the present disclosure and their potential effects are treated as if they were described in the specification of the present disclosure.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a reference cross-sectional view to illustrate misalignment occurring in a conventional via stack structure;

FIG. 2 is a cross-sectional view illustrating a semiconductor device according to an embodiment of the present disclosure; and

FIGS. 3 to 17 are reference diagrams for illustrating a method of manufacturing a semiconductor device according to an embodiment of the present disclosure.

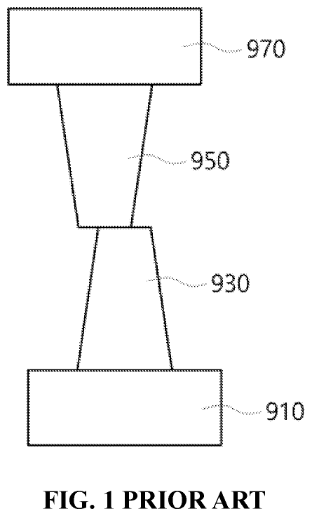

### DETAILED DESCRIPTION OF THE INVENTION

Hereinafter, embodiments of the present disclosure will be described in detail with reference to the accompanying drawings. It is noted that embodiments of the present disclosure may be changed to a variety of embodiments. The scope of the present disclosure should not be interpreted as being limited to the embodiments described hereinbelow, but should be interpreted on the basis of the descriptions in the appended claims. In addition, the embodiments of the present disclosure are provided for reference in order to fully describe the disclosure for those skilled in the art.

In addition, it should be noted that, where certain embodiments are otherwise feasible, certain process sequences may be performed other than those described below. For example, two processes described in succession may be performed substantially simultaneously or in the reverse order.

It should be noted that, in a case where one element (layer) is described as being arranged on the top of one other element (layer), this means that the one element may be arranged directly on the top of the one other element or that a third element(s) or layer(s) may be arranged therebetween. In addition, in the case where one element is described as being arranged on the top of one other element, a third element(s) is not positioned therebetween. In addition, positioning on a “top”, “upper portion”, or “lower portion” of one element, positioning “above” or “below” one element, or positioning on “one lateral side”, or a “lateral surface” of one element means a relative positional relationship.

In the following, although the explanation is based on a resistive switching memory device used as a resistive random-access memory (ReRAM) device as one of the non-volatile semiconductor memories, it should be noted that a stacked via structure according to the present disclosure is not necessarily limited to resistance switching memory devices.

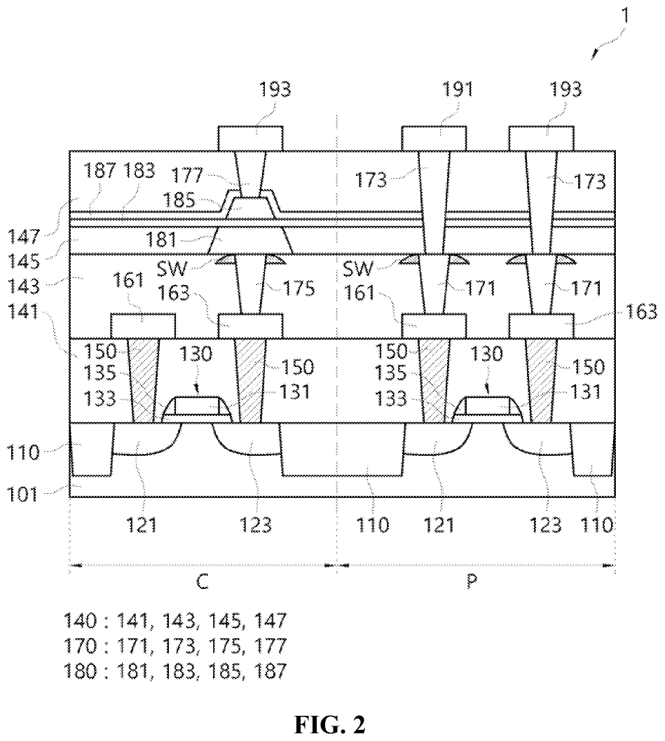

FIG. 2 is a cross-sectional view illustrating a semiconductor device according to an embodiment of the present disclosure.

Hereinafter, a semiconductor device 1 including a stacked via structure according to an embodiment of the present disclosure will be described in detail with reference to the attached drawings.

Referring to FIG. 2, the present disclosure relates to a semiconductor device 1 including a stacked via structure and, more particularly, to a semiconductor device 1 that ensures a sufficient alignment margin between upper and lower vias by forming a conductive sidewall at an upper end of the lower via or a lower end of the upper via to surround the upper or lower end in a stacked via structure.

The semiconductor device 1 according to an embodiment of the present disclosure may include a cell region C including a memory cell 180 and a peripheral region P as a logic area around the cell region C. However, as described above, it should be noted that the stacked via structure according to an embodiment of the present disclosure is applicable to any semiconductor device.

The structure of the semiconductor device 1 according to an embodiment of the present disclosure will be described. First, a substrate 101 may be formed. The substrate 101 may be, for example, a bulk substrate or a silicon-on-insulator (SOI) substrate and there is no particular limitation thereon. In addition, one or more device isolation layers 110 may be formed within the substrate 101 to define an active region, and the device isolation layer 110 may be formed by a shallow trench isolation (STI) process. The device isolation layer 110 may also be formed on the boundary between the cell region C and the peripheral region P.

A source region 121 and a drain region 123 may be formed in the substrate 101. The source region 121 and the drain region 123 are spaced apart from each other on the surface side of the substrate 101, and may be formed within a pair of adjacent device isolation layers 110. The source region 121 and the drain region 123 may be formed in the cell region C and the peripheral region P by an impurity ion implantation process.

In addition, a gate region 130 may be formed on the substrate 101. The gate region 130 is formed in both the cell region C and the peripheral region P, and may be formed between a pair of adjacent source region 121 and drain region 123 at a location partially overlapping with the source region 121 and drain region 123. The gate region 130 may include a gate electrode 131, a gate insulation film 133, and a gate spacer 135. First, the gate electrode 131 may include, for example, any one of conductive polysilicon, metal, conductive metal nitride, and a combination thereof.

In addition, the gate insulation film 133 is formed between the gate electrode 131 and the surface of the substrate 101 under the gate electrode 131, and may include, for example, any one of a silicon oxide layer, a high-k dielectric layer, and a combination thereof. The gate spacer 135 is configured to cover the sidewall of the gate electrode 131 and may include, for example, one of an oxide film, a nitride film, and a combination thereof.

Continuing the description, an interlayer insulation film 140 may be formed on the substrate 101 to cover the substrate 101 and the gate electrode 130. The interlayer insulation film 140 may be formed by using, for example, a borophosphosilicate glass (BPSG) film and a tetraethyl orthosilicate (TEOS) film, but the scope of the present disclosure is not limited thereto. In addition, the interlayer insulation film 140 may include a first insulation film 141, a second insulation film 143, a third insulation film 145, and a fourth insulation film 147 sequentially stacked upward.

A contact plug 150 may be formed within the interlayer insulation film 140, preferably within the first insulation film 141. The contact plug 150 is formed in both the cell region C and the peripheral region P and may be electrically connected to the individual source region 121 and drain region 123. Accordingly, the contact plug 150 may be formed in a number that corresponds one to one with the source region 121 and the drain region 123, and may include a conductive material, for example, W. The contact plug 150 extends in the vertical direction within the first insulation film 141. The contact plug 150 may be formed such that the left-right width thereof may become narrower as the outer surface thereof extends downward or may be extended to have substantially the same left-right width size, and there is no particular limitation thereon.

In addition, within the interlayer insulation film 140, preferably within the second insulation film 143, a first source metal 161 and a first drain metal 163 may be formed to be spaced apart from each other. The first source metal 161 may be electrically connected to the source region 121 by one contact plug 150, and the first drain metal 163 may be electrically connected to the drain region 123 by the other contact plug 150. The first source metal 161 and the first drain metal 163 are formed in both the cell region C and the peripheral region P, and may include, for example, conductive materials such as Ti and/or TiN. In addition, the first source metal 161 and the first drain metal 163 may be formed on the lower side of the second insulation film 143, and the bottoms thereof may be physically or electrically connected to the corresponding individual contact plugs 150.

A via 170 may be formed within the interlayer insulation film 140. The via 170 includes a conductive material and may include W, for example. Individual vias 170 may extend along the vertical direction within the interlayer insulation film 140.

Describing the via 170 in detail, the via 170 may include a lower via and an upper via. In the cell region C, a memory cell 180 may be formed between a lower via 175 and an upper via 177. Thus, in the cell region C, the lower via 175 and the upper via 177 do not form a stacked structure. On the other hand, in the peripheral region P, the lower via 171 and the upper via 173 are directly connected to each other in a one-to-one correspondence and have a stacked structure, which is referred to as a “stacked via structure”.

For convenience of explanation, the lower via of the peripheral region P is referred to as a “first lower via 171”, and the upper via of the peripheral region P is referred to as a “first upper via 173” whereas the lower via of the cell region C is referred to as a “second lower via 175”, and the upper via of the cell region C is referred to as a “second upper via 177”. In addition, the individual via 170 may have substantially the same outer shape as the contact plug 150, and detailed description thereof will be omitted.

A plurality of first lower vias 171 are formed within the interlayer insulation film 140, preferably within the second insulation film 143. The first lower via 171 is physically or electrically connected to the individual first source metal 161 and first drain metal 163 in the peripheral region P. Each first lower via 171 extends up and down, and the bottom thereof may be connected to the individual first source metal 161 and the first drain metal 163, and the upper part thereof may be connected to the individual first upper via 173.

A plurality of first upper vias 173 are formed within the interlayer insulation film 140, preferably within the third insulation film 145 and the fourth insulation film 147, and is physically or electrically connected to the individual first lower vias 171. The first upper via 173 extends up and down, and the bottom thereof may be connected to the corresponding first lower via 171 while the upper part thereof may be connected to an individual second source metal 191 and second drain metal 193. The first upper via 173 may be formed in a structure that penetrates a switching layer 183 and an insulation film layer 187 within the third and fourth insulation films 145 and 147.

In addition, the second lower via 175 is formed within the interlayer insulation film 140, preferably within the second insulation film 143, and is physically or electrically connected to the first drain metal 163 in the cell region C. The second lower via 175 extends up and down, and the bottom thereof may be connected to first drain metal 163 while the upper part thereof may be connected to the memory cell 180 or a lower electrode 181.

In addition, the second upper via 177 is formed within the interlayer insulation film 140, preferably within the fourth insulation film 147, and is connected to the memory cell 180. That is, the memory cell 180 may be formed between the second lower via 175 and the second upper via 177. In addition, the second upper via 177 may penetrate the insulation film layer 187 within the fourth insulation film 147 and be physically or electrically connected to an upper electrode 185.

Hereinafter, the structure of the memory cell 180 formed in the cell region C will be described in detail. First, the lower electrode 181 may be formed within the interlayer insulation film 140, preferably within the third insulation film 145. The lower electrode 181 may be formed on the second lower via 175 within the cell region C. The lower electrode 181 may include, for example, Ti and/or TiN, and may have a lateral width whose lower end is larger than the upper end of the second lower via 175. In this way, as the width of the lower end of the lower electrode 181 is formed to be larger than the width of the upper end of the second lower via 175, even if misalignment occurs between the lower electrode 181 and the second lower via 175, a sufficient alignment margin may be ensured.

The switching layer 183 may be formed between the third insulation film 145 and the fourth insulation film 147 on the lower electrode 181. The switching layer 183 is configured to physically separate the lower electrode 181 and the upper electrode 185, and may undergo a reversible change between a high-resistance state and a low-resistance state depending on the voltage applied to the pair of electrodes 181 and 185. The switching layer 183 is an insulation layer and may include, for example, HfO₂, Al₂O₃, or NiOₓ. The switching layer 183 may be formed on the third insulation film 145 in both the cell region C and the peripheral region P, and there is no particular limitation thereon.

In addition, the upper electrode 185 may be formed on the switching layer 183. The upper electrode 185 includes a conductive material and may include, for example, Al or Pt. The upper electrode 185 may be physically or electrically connected to the second upper via 177. The upper electrode 185 may have a lateral width whose upper end is larger than the lower end of the second upper via 177. In this way, as the width of the upper end of the upper electrode 185 is formed to be larger than the width of the lower end of the second upper via 177, even if misalignment occurs between the upper electrode 185 and the second upper via 177, a sufficient alignment margin may be ensured.

The insulation film layer 187 may be formed on the upper electrode 185 to cover the upper electrode 185. The insulation film layer 187 may be formed on the switching layer 183. In addition, the insulation film layer 187 may include for example, SiN, but there is no particular limitation thereon.

As previously described, in the cell region C, the lower end of the lower electrode 181 has a lateral width larger than the upper end of the second lower via 175, and the upper end of the upper electrode 185 has a lateral width larger than the lower end of the second upper via 177. Accordingly, even if misalignment occurs when forming vias 175 and 177, sufficient margin may be ensured.

However, in the peripheral region P, since the ends of the first lower via 171 and the first upper via 173 form a stacked via structure in which the ends are directly connected to each other, when misalignment occurs, electrical signals may not be properly applied to the device. If the width of the vias 175 and/or 177 is made large to prevent misalignment, that is, for alignment stability, pitches in a via formation process increase, which causes the problem of increasing the overall size of the device. To prevent misalignment while maintaining the width size of the via (175 and/or 177), additional masks or high-performance equipment need to be used to accurately perform a process, which may significantly increase manufacturing costs.

In order to prevent such problems, in the semiconductor device 1 according to the embodiment of the present disclosure, a sidewall SW is formed on one side of the via 170. Although in the drawing, the sidewall SW is shown as being formed at the upper end of the first lower via 171 in the peripheral region P, but it should be noted that in some cases, the sidewall SW may be formed at the lower end of the first upper via 173. In addition, the sidewall SW may be formed only in the peripheral region P, but is preferably formed in both the peripheral region P and the cell region C for process efficiency.

As an example, the sidewall SW is formed within the interlayer insulation film 140, preferably within the second insulation film 143 to surround the upper outer surface of the first lower via 171. The sidewall SW is a conductive metal material and may include, for example, W. As described above, the sidewall SW may be formed to surround not only the first lower via 171 but also the upper outer surface of the second lower via 175 in the cell region C.

In addition, as will be explained in detail below, the sidewall SW is formed by deposition and removal processes without using a separate mask pattern, and thus the sidewall SW, like the gate spacer 135, is preferably formed such that the bottom surface thereof is substantially flat, but the upper surface thereof has a curved side. By forming the sidewall SW in this way, it is possible to secure an alignment margin larger than the width of the upper end of the first lower via 171, thereby securing a sufficient contact area even when misaligned with the first upper via 173. At this time, the width of the sidewall SW should be understood to mean the width of the surface on which the second lower via 173 may make contact.

Finally, the second source metal 191 and the second drain metal 193 may be formed spaced apart within the interlayer insulation film 140, preferably within the fourth insulation film 147. The second source metal 191 is configured to physically or electrically connected to the first upper via 173 in the peripheral region P. In addition, the second drain metal 193 may be physically or electrically connected to the individual first upper via 173 in the cell region C and the peripheral region P. The second source metal 191 and the second drain metal 193 may include a conductive material such as Ti and/or TiN, for example.

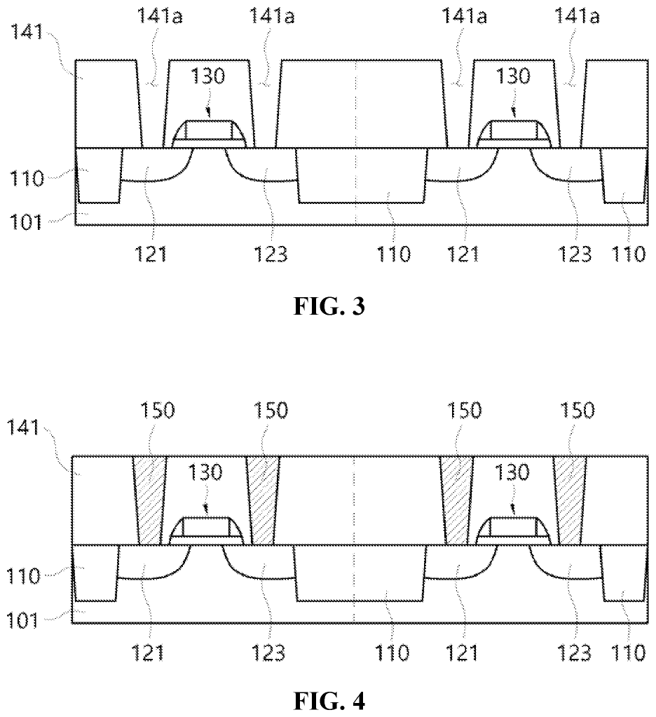

FIGS. 3 to 17 are reference diagrams for illustrating a method of manufacturing a semiconductor device according to an embodiment of the present disclosure.

Hereinafter, a method of manufacturing a semiconductor device according to an embodiment of the present disclosure will be described in detail with reference to the attached drawings. Hereinafter, for convenience of explanation, only the process after forming a source region 121 and a drain region 123 in a substrate 101, and a gate region 130 on the substrate 101 will be described in detail.

Referring to FIG. 3, first, on the substrate 101, a first insulation film 141 is deposited to a predetermined height to cover the gate region 130. Thereafter, a contact hole 141a is formed in the first insulation film 141 to form a contact plug 150. The contact hole 141a has a shape that penetrates the first insulation film 141 up and down, and may be formed in a number that corresponds one-to-one with the individual source region 121 and drain region 123.

Thereafter, referring to FIG. 4, the contact plug 150 may be formed by gap-filling the individual contact hole 141a. As an example, after forming a conductive film (not shown) on the first insulation film 141 and in the contact hole 141a, the contact plug 150 may be formed by removing the conductive film deposited on the first insulation film 141.

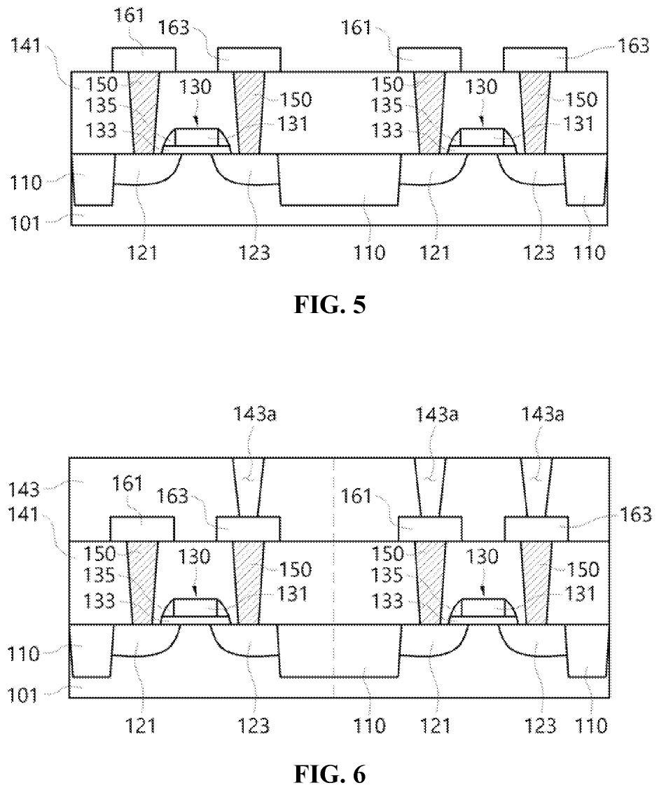

Thereafter, referring to FIG. 5, lower metals that include a first source metal 161 and a first drain metal 163 are formed on the first insulation film 141. The first source metal 161 and the first drain metal 163 may be connected to the contact plug 150 thereunder. The first source metal 161 and the first drain metal 163 may be formed, for example, by forming a conductive film (not shown) on the first insulation film 141 and then patterning the conductive film.

Thereafter, referring to FIG. 6, on the first insulation film 141, a second insulation film 143 is deposited to a predetermined height to cover the individual first source metal 161 and first drain metal 163.

After forming the second insulation film 143, a via hole 143a is formed for forming lower vias 171 and 175 in the second insulation film 143. The term “lower via” is a concept that includes both the first lower via 171 and the second lower via 175. In addition, the via hole 143a may have a shape that penetrates the second insulation film 143 up and down.

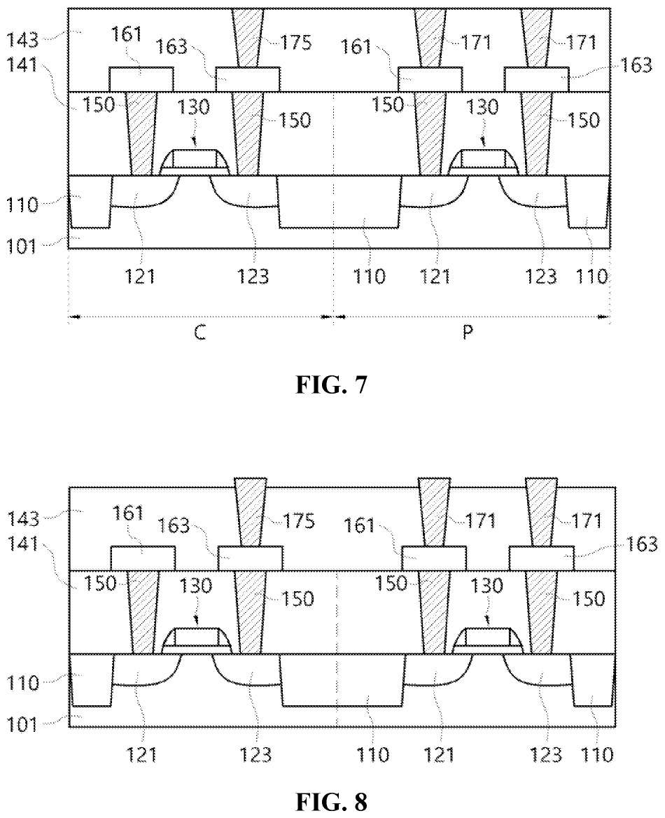

Thereafter, referring to FIG. 7, after forming a conductive film (not shown) in the via hole 143a, the first lower via 171 and the second lower via 175 may be formed by removing the conductive film deposited on the second insulation film 143.

Thereafter, referring to FIG. 8, the upper surface of the second insulation film 143 is removed or etched to a predetermined depth. As a result, the upper portions of the lower vias 171 and 175 may be exposed to the outside. The etch depth of the second insulation film 143 may be substantially equal to the top and bottom thickness of a sidewall SW.

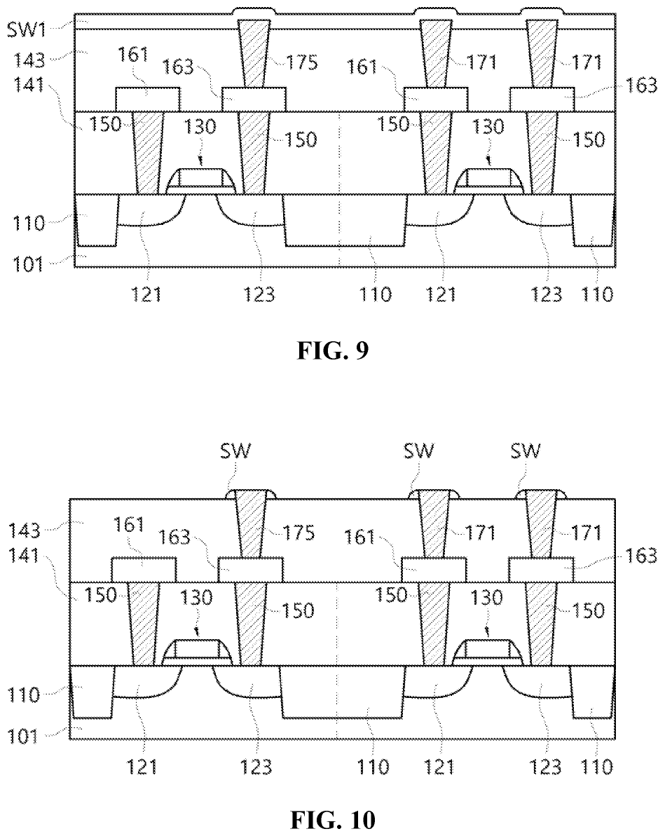

Thereafter, referring to FIG. 9, a conductive film SW1 is deposited to cover the exposed upper portions of the lower vias 171 and 175 on the upper surface of the second insulation film 143. The conductive film SW1 may be W, for example, but the scope of the present disclosure is not limited thereto.

Thereafter, referring to FIG. 10, the deposited conductive film SW1 is etched without a separate mask pattern. At this time, a sidewall SW may be naturally formed along the sidewalls of the exposed lower vias 171 and 175. In addition, as previously described, although the possibility of misalignment issues with the upper and lower vias 175 and 177 is extremely low in the cell region C, for process efficiency, it is desirable to form a sidewall SW as in the peripheral region P.

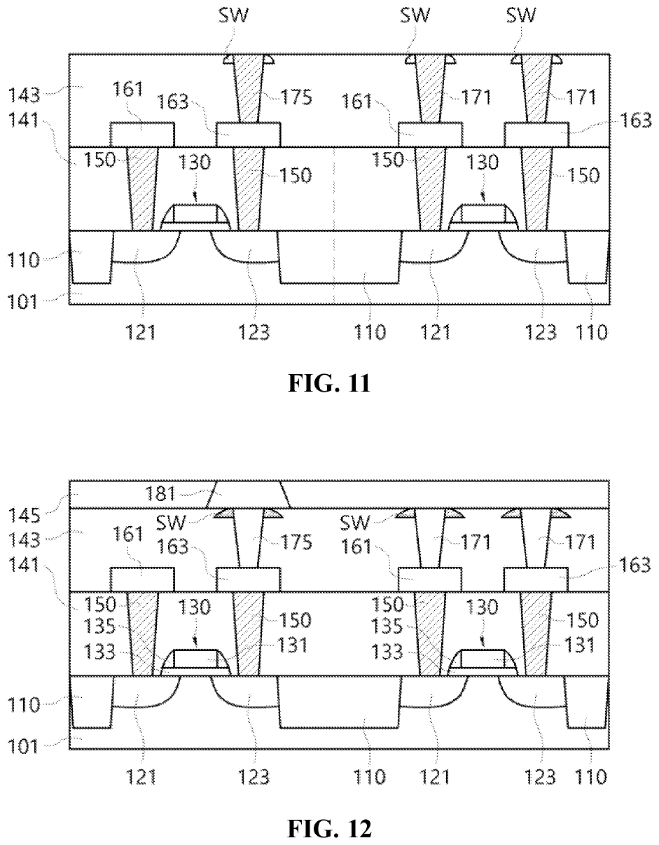

Thereafter, referring to FIG. 11, on the second insulation film 143, an additional insulation film may be formed to cover the side of the sidewall SW, thereby completing the second insulation film 143.

Thereafter, referring to FIG. 12, after forming a lower electrode 181 on the second insulation film 143, a third insulation film 145 may be formed to cover the sidewall of the lower electrode 181. The lower electrode 181 may be formed by forming a conductive film (not shown) on the second insulation film 143 and then patterning the conductive film.

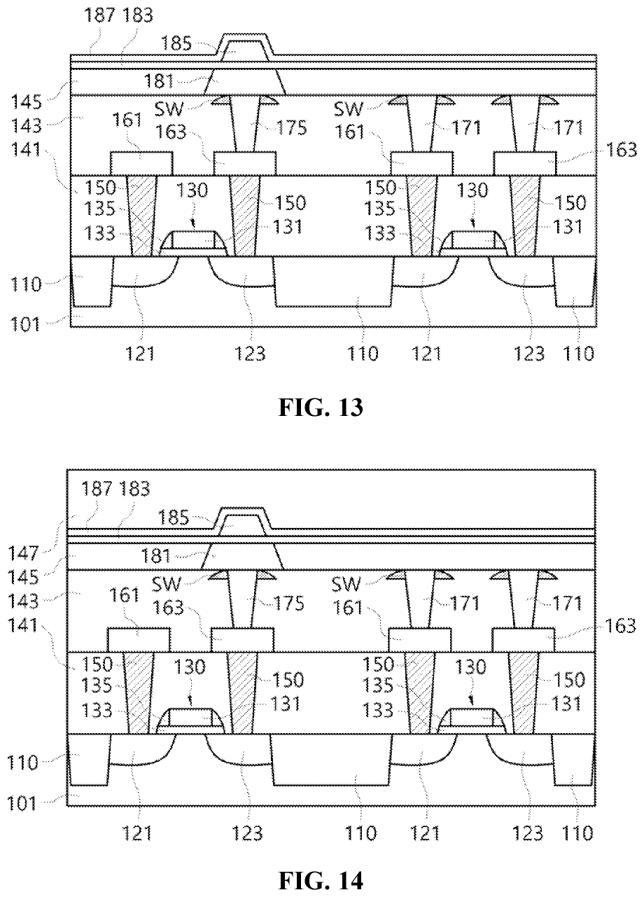

Thereafter, referring to FIG. 13, a switching layer 183, an upper electrode 185, and an insulation film layer 187 may be sequentially formed on the third insulation film. The upper electrode 185, like the lower electrode 181, may be formed by forming a conductive film (not shown) on the switching layer 183 and then patterning the conductive film.

Thereafter, referring to FIG. 14, a fourth insulation film 147 is deposited at a predetermined height on the insulation film layer 187 to cover a memory cell 180.

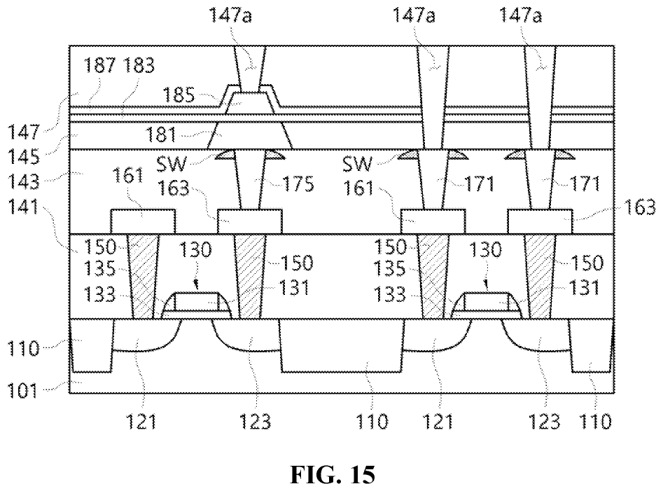

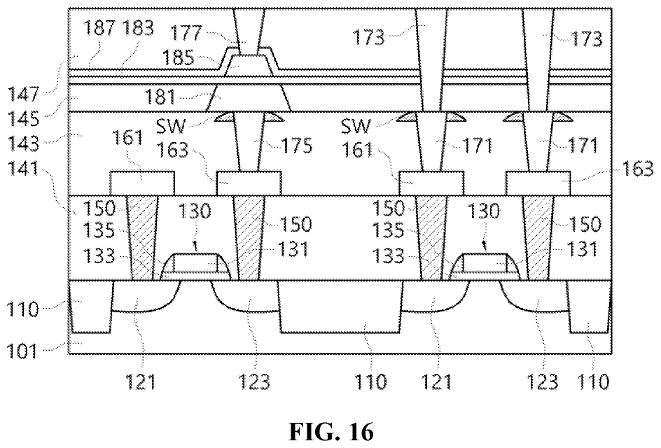

After forming the fourth insulation film 147, upper vias 173 and 177 are formed. The term “upper via” is a concept that includes both the first upper via 173 and the second upper via 177. The upper vias 173 and 177 may be formed after forming, referring to FIG. 15, a via hole 147a in the fourth insulation film 147 (a via hole is additionally formed in the third insulation film 145 in the peripheral region P), and after forming, referring to FIG. 16, a conductive film (not shown) on the fourth insulation film 147 and in the via hole 147a, and then by removing the conductive film on the fourth insulation film 147.

In this case, the via hole 147a in the cell region C may be formed through the insulation film layer 187 up to the side where the upper surface of the upper electrode 185 is exposed, whereas the via hole 147a in the peripheral region P may be formed up to the side where the upper end of the first lower via 171 is exposed.

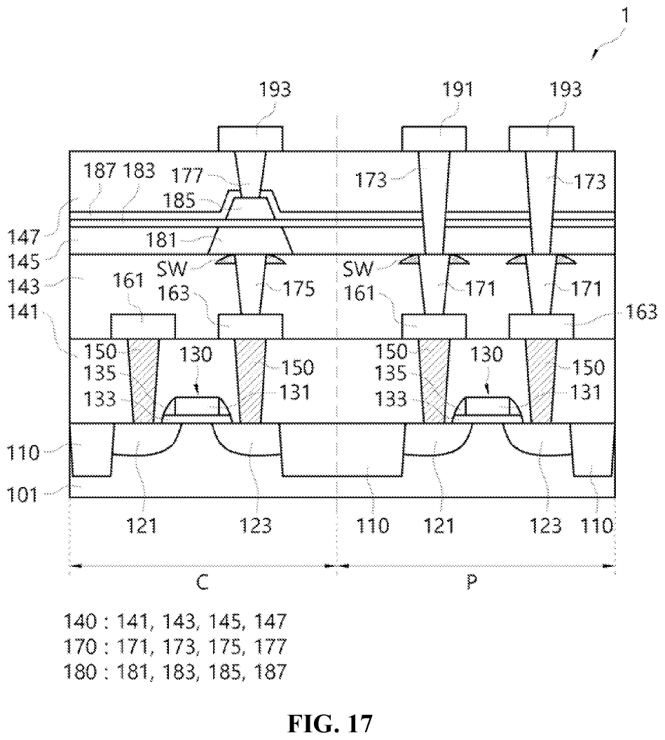

Finally, referring to FIG. 17, upper metals that include a second source metal 191 and a second drain metal 193 may be formed on the fourth insulation film 147. The second source metal 191 and the second drain metal 193 may be connected to the upper vias 173 and 177 thereunder. The second source metal 191 and the second drain metal 193 may be formed, for example, by forming a conductive film (not shown) on the fourth insulation film 147 and then patterning the conductive film.

The foregoing detailed description illustrates the present disclosure. In addition, the foregoing illustrates and describes the preferred embodiments of the present disclosure and the present disclosure may be utilized in various other combinations, modifications and environments. That is, it is possible to make changes or modifications within the scope of the concept of the disclosure disclosed herein, within the scope of equivalents to the above-described disclosure, and/or within the scope of the skill or knowledge of the art. The above-described embodiments are intended to describe the best mode for carrying out the technical spirit of the present disclosure, and various modifications required in the specific applications and uses of the present disclosure are possible. Accordingly, the foregoing detailed description is not intended to limit the present disclosure to the embodiments disclosed.

What is claimed is:

1. A stacked via structure comprising:
a first source metal and a first drain metal disposed apart from each other in an interlayer insulation film;
a pair of lower vias, wherein one of the pair of lower vias is connected to the first source metal and the other of the pair of lower vias is connected to the first drain metal within the interlayer insulation film;
a pair of upper vias, wherein one of the pair of upper vias is connected to an upper part of the one of the pair of lower vias and the other of the pair of upper vias is connected to an upper part of the other of the pair of lower vias within the interlayer insulation film;
a second source metal connected to the one of the pair of upper vias and a second drain metal connected to the other of the pair of upper vias, wherein the second source metal and the second drain metal are disposed apart from each other, and
a sidewall disposed at an end of each of the pair of lower vias or at an end of each of the pair of upper vias to surround the end.

2. The stacked via structure of claim 1, wherein the sidewall has a conductive metal material.

3. The stacked via structure of claim 2, wherein the sidewall surrounds an upper outer surface of each of the pair of lower vias.

4. The stacked via structure of claim 2, wherein the sidewall is formed by an etching process without a separate mask pattern.

5. The stacked via structure of claim 2, wherein the sidewall has a flat bottom surface and a curved upper surface.

6. A semiconductor device including a stacked via structure, the semiconductor device comprising:
a substrate;
a plurality of gate regions disposed on the substrate, one of the plurality of gate regions being disposed in a cell region and another of the plurality of gate regions being disposed in a peripheral region;
a source region and a drain region disposed in the cell region and another source region and another drain region disposed in the peripheral region, wherein the source region and the drain region are disposed apart from each other and the another source region and the another drain region are disposed apart from each other within the substrate;
a plurality of contact plugs, a first contact plug being connected to the source region, a second contact plug being connected to the drain region, a third contact plug being connected to the another source region, and a fourth contact plug being connected to the another drain region;
a first source metal connected to the first contact plug, a first drain metal connected to the second contact plug, another first source metal connected to the third contact plug, and another first drain metal connected to the fourth contact plug, wherein the first source metal and the first drain metal are disposed apart from each other and the another first source metal and the another first drain metal are disposed apart from each other;
a pair of first lower vias, wherein one of the pair of first lower vias is connected to the another first source metal and the other of the pair of first lower vias is connected to the another first drain metal in the peripheral region;
a pair of first upper vias, wherein one of the pair of first upper vias is connected to an upper end of the one of the pair of first lower vias and the other of the pair of first upper vias is connected to an upper end of the other of the pair of first lower vias in the peripheral region; and
a sidewall disposed on an end of each of the pair of first lower vias.

7. The semiconductor device of claim 6, further comprising:
a second lower via connected to the first drain metal in the cell region;
a memory cell connected to an upper part of the second lower via in the cell region; and
a second upper via connected to an upper side of the memory cell in the cell region.

8. The semiconductor device of claim 7, wherein the memory cell comprises:
a lower electrode connected to the upper part of the second lower via;
a switching layer disposed on the lower electrode;
an upper electrode disposed on the switching layer; and
an insulation film layer disposed on the upper electrode.

9. The semiconductor device of claim 8, wherein the sidewall is disposed at an upper end of each of the pair of first lower vias or at an upper end of the second lower via, the sidewall surrounding the upper end of each of the pair of first lower vias or the upper end of the second lower via.

10. The semiconductor device of claim 8, wherein the sidewall has a conductive metal material.

11. The semiconductor device of claim 8, wherein the lower electrode has a bottom surface that has a width larger than a width of a top surface of the second lower via.

12. The semiconductor device of claim 8, wherein the upper electrode has a top surface that has a width larger than a width of a bottom surface of the second upper via.

13. The semiconductor device of claim 8, wherein the sidewall has an upper surface configured to contact a bottom surface of each of the pair of first upper vias.

14. A method of manufacturing a semiconductor device including a stacked via structure, the method comprising:
forming a first insulation film on a substrate;
forming a contact plug within the first insulation film;
forming a lower metal connected to the contact plug on the first insulation film;
forming a second insulation film on the first insulation film to cover the lower metal;
forming a lower via in the second insulation film;
etching an upper surface of the second insulation film to expose an upper side of the lower via;
forming a conductive film on the second insulation film; and
forming a sidewall surrounding the upper side of the lower via by etching the conductive film.

15. The method of claim 14, wherein the sidewall is formed by an etching process without a separate mask pattern.

16. The method of claim 14, further comprising:
completing the second insulation film by forming an insulation film up to an upper end of the lower via on the second insulation film that is etched.

17. The method of claim 16, further comprising:
forming an additional insulation film on the second insulation film; and
forming an upper via connected to the lower via in the additional insulation film to form a stacked via structure.

18. The method of claim 17, further comprising:
forming an upper metal connected to the upper via on the upper via.

19. The method of claim 17, wherein at least one area of an upper surface of the sidewall is not covered by the second insulation film.
